(19) United States
(12) Patent Application Publication
(10) Pub. No.: US 2009/0218589 A1
(43) Pub. Date: Sep. 3, 2009

(54) Semiconductor die with reduced thermal boundary resistance

(75) Inventors: Scott M. Zimmerman, Basking Ridge, NJ (US); Karl W. Beeson, Princeton, NJ (US); William R. Livesay, San Diego, CA (US); Richard L. Ross, Del Mar, CA (US)

Correspondence Address: Goldeneye, Inc., Suite 233, 9747 Businesspark Avenue, San Diego, CA, 92131, US

(73) Assignee: Goldeneye, Inc.

(21) Appl. No.: 12/380,470

(22) Filed: Feb. 27, 2009

Related U.S. Application Data
(60) Provisional application No. 61/067,935, filed on Mar. 1, 2008.

(51) Int. Cl. H01L 33/00; H01L 29/12

(52) U.S. Cl. 257/99; 257/191; 257/613; 257/712; 257/E33.066; 257/E29.068

(57) ABSTRACT

Thermal boundary resistances within nitride semiconductor LEDs are reduced or eliminated by forming a thick nitride epitaxial layer, which can be separated from a growth substrate, and by reducing the number of thermal boundary layers during laser lift-off. The thermal boundary resistances within nitride semiconductor LEDs can also be reduced or eliminated by forming a plurality of thin nitride epitaxial layers.

### REFERENCE TO PRIOR APPLICATION

This application claims the benefit of U.S. Provisional Patent Application Ser. No. 61/067,935, which was filed on Mar. 1, 2008, which is herein incorporated by reference.

### BACKGROUND OF THE INVENTION

High powered semiconductor devices such as light emitting diodes (LEDs), laser diodes, HEMTs, and concentrated solar cells, are limited by their overall thermal impedance. Nitrides as the semiconductor material in the semiconductor devices in particular represent a difficult problem for cooling due to the high thermal flux density, which the nitrides enable, based on their superior material properties. In the case of HEMTs, tens of watts/mm2 are typically used with hundreds of watts/mm2 under development. In the case of LEDs and laser diodes, similar power densities are required for high lumen and high brightness applications. In the case of concentrated solar cells, hundreds of suns of incident solar flux impinge on the devices of which some percentage results in device heating. In each of these cases the thermal impedance of the devices to ambient cooling must be minimized.

The minimization of thermal impedance is a complex thermal problem not only because of the power levels involved but because of the number of semiconductor layers that can make up these devices. In solids, thermal conduction consists of free electron diffusion in metals and phonons (vibrational modes) in insulators. For the purpose of this invention, phonons will be considered the dominate means of thermal conduction within the nitride semiconductor devices being discussed. In addition, the concept of phonons flowing from the hotter active region to the cooler cooling means as the direction of phonon flow will be used. Even the internal epitaxial layers which are based on alloys of various nitrides can have significant impact on the overall device performance due to the reflection of phonons across these boundaries which leads to an impediment of phonon flow or a reduction in thermal conduction. As such, a complete thermal analysis must take into account these interfaces and how they tend to localize heating especially at very high power density levels.

A number of techniques have been employed in order to maximize nitride semiconductor device performance. Typically nitrides are grown or mounted on high thermal conductivity substrates such as SiC, AlN, and Diamond. While these materials do exhibit high thermal conductivity, their effectiveness is limited by how well heat can be transferred from the active region into these heat spreading layers. Even if the active region is epitaxially grown on the heat spreading layer, thermal barriers are created at any interface where there is a significant composition change. In a manner similar to how photons undergo fresnel reflections at abrupt changes in refractive index, phonons can be reflected or scattered by any significant atomic boundary layer that is created between two distinct materials. This phonon reflection or scatter has limited the effectiveness of diamond and other high thermal conductivity materials.

The problem is not conducting the heat through the high thermal conductivity materials; the problem is getting the heat into the high thermal conductivity material from the nitride active region in the first place. In these non-native substrate cases, this effect is further compounded by the growth techniques typically used to initiate nitride epitaxial growth, such as low temperature nucleation layers and surface texturing, which all tend to increase the thermal boundary resistance at these interfaces. As shown by K. A. Filippov and A. A. Balandin, “Self-Heating Effects in GaN/AlGaN Heterostructure Field-Effect Transistors and Device Structure Optimization”, in Proceed of Nanotech 2003, Volume 3, pp. 333-336 (2003), a single GaN and SiC epitaxial boundary can lead to an increase in the junction temperatures by 10 to 20 degrees C. when power densities exceed 10 s of watts/mm2. In this case it does not matter how high the thermal conductivity of the two semiconductor materials being used is, what matters is the boundary which is created because the two semiconductor materials are not the same. This can also be the case within the device structure itself.

The use of p contact down semiconductor devices would seem to offer the ideal thermal impedance path for a device based on the close proximity of the active region to the cooling mean. However, in many devices such as LEDs, AlGaN barrier layers are used on the p side of the semiconductor structure to control electron leakage at high current densities. These barrier layers are required because of the higher mobility of electrons relative to holes that exist within nitrides. The interface created within the device between the AlGaN and GaN layers can lead to localization of thermal phonons within the active region in a similar manner to how the electrons are being localized by the barrier layer. This localization leads to a conflict for the device designer, in that what is good for electrical performance may not necessarily be good for thermal performance of the device if the direction of phonon flow is substantially the same direction as electron flow. In general, at high power densities, the reflection of phonons within the very thin layers required for p-N junctions, single quantum wells, multiple quantum wells, 2DEG, or any semiconductor structure can adversely affect the thermal performance of the device by localizing the heat within the active regions of the device. Essentially a thermal cavity can be formed which traps the heat in close proximity to active region of the semiconductor device. This trapped heat can manifest itself as droop, lower peak operating levels, and decreases in other performance parameters. In addition, since nitrides are both piezoelectric and pyroelectric in nature, internal fields generated by thermal effects and stresses generated by thermal effects between the various compositionally different layers in an semiconductor device can have significant impact on overall device performance.

The key to reducing thermal boundary interfaces is the use of native nitride substrates and the design of epitaxial structure with the minimum number thermal boundary interfaces between the active region and the cooling means. The phonon direction should be substantially different from the direction of electron flow. Both non-native layers and alloys of the native substrate internal and external to the device structure must be considered in the design of the device.

While freestanding nitride devices have been demonstrated based on nitride wafers and the disclosed techniques can be used for devices grown on nitride wafers, nitride wafers are expensive and contain a large number of defects based on surface polishing and slicing processes required to form the wafers. Typically, a 1 cm thick GaN boule is grown on sapphire or some other growth substrate using HVPE. The 1 cm thick GaN boule is sliced into 300 to 400 micron thick wafers and then polished in a manner similar to silicon wafers. While the average dislocation defect density of these wafers maybe below 10(6) cm2, the stresses and surface defects introduced during slicing and polishing steps are significant. In addition, a variable miscut is created across the wafer due to bow and warp characteristics of the boule. This leads to non-uniform growth and variability in device performance.

What is needed is the ability to combine the high thermal conductivity of native growth substrates with semiconductor device designs, which eliminate or mediate the effects of thermal boundary layers such that maximum device performance can be realized. Inherent to this disclosure is the realization that localization of the heat within the active region of any semiconductor device is detrimental to the performance of the device. In addition the realization that thermal boundary resistance can dominate the thermal impedance of the high powered semiconductor devices is disclosed.

The intent of this present invention is to disclose semiconductor device designs based on the use of thin flexible epitaxial-ready native nitride substrates, which eliminate or reduce thermal boundary layers between the active region and cooling means of the device. It is critical that a thin native substrate be used to eliminate non-nitride interfaces and to allow for access to both sides of the structure. In this manner, the direction of phonon flow can be substantially different from electron flow within the device. In addition the formation of devices with increased surface area in contact with the cooling means based on flexible native nitride substrates is disclosed. In general, the need exists for die designs, which minimize the effects of thermal boundary resistance in a wide range of high powered devices.

### SUMMARY OF THE INVENTION

This invention discloses nitride semiconductor structure design and the processes to make those structures, which reduce and in some cases eliminate unnecessary thermal boundary resistances within semiconductor devices.

The use of native substrates in the semiconductor devices allows the elimination of non-native thermal boundary interfaces with the semiconductor device itself. The direction of phonon flow can be substantially different than electron flow within the semiconductor device.

HVPE can form a nitride epitaxial layer thick enough to be separated from a growth substrate such as sapphire and allow for subsequent processing including, but not limited to, semiconductor device growth, contact formation, and dicing, yet thin enough so that additional thinning processes are not required for the finished semiconductor structure. The quality of this nitride layer is critical to allow for sufficient thickness for a handling while maintaining a low thermal impedance path through the semiconductor device itself. HVPE is preferred for these applications due to its high growth rate and high crystal quality.

Thermal conductivity for GaN is typically considered much lower than SiC or AlN. This low thermal conductivity however is due mainly to the lack of high quality GaN crystals. Both dislocations and impurities degrade typical GaN thermal conductivity to less than 120 W/m/K. From a theoretical standpoint, GaN has been predicted to have a thermal conductivity greater than 400 W/m/K. By using HVPE growth with greater than 20 microns of thickness, greater than 120 W/m/K thermal conductivity material can be achieved and structural integrity for even large area dies can be made without the need for an additional supporting submount. Even epitaxial layers can introduce thermal discontinuities within semiconductor devices. If the thermal conductivity of the bulk material is high enough and the power density within the semiconductor device is high enough, the majority of the thermal impedance then becomes these thermal boundary interfaces. Because these interfaces are discontinuities that are essentially fixed. As the power density increases, their relative importance versus bulk thermal conductivity increases till eventually the interfaces dominate the overall thermal impedance of the device.

While techniques exist for transferring thin epitaxial layers to supporting structures, the result is always the introduction of additional thermal boundary layers. The typical laser liftoff LED consists of almost a dozen thermal boundary layers if all the epitaxial and deposited layers are included. Each one of these layers represents a reflection point to phonons conducting the heat away from the active region. Each discontinuity can introduce several degrees C. temperature drop at power densities of 10 watts/mm2. Conversely, the bulk thermal conductivity of a 50 micron thick layer 1 mm2 layer with a thermal conductivity of 400 W/mK can transfer 10 watts with less than 1 C temperature drop steady state. The transient effects of these thermal boundary layers are also significant especially if they are close to the active region. As such the proper combination of bulk thermal conductivity and semiconductor device design can lead to significant improvement in overall semiconductor device performance.

A key element of this invention is the formation of a sufficiently thick enough HVPE layer to permit handling and packaging and its separation from any growth substrate such as, but not limited, to sapphire, SiC, AlN, and diamond and its use to eliminate or reduce thermal boundary layers within the device.

### BRIEF DESCRIPTION OF THE DRAWINGS

FIG. 1 is a side view of a phosphor coated, flip chip mounted LED.

FIG. 2 is a side view of a temperature discontinuity across an epitaxial layer between two semiconductor material layers.

FIG. 3 is a side view of thermal boundary layers in a laser liftoff LED.

FIG. 4 is a side view of a freestanding epitaxial chip with reduced thermal boundary layers of the present invention.

FIG. 5 is a side view of a single heterojunction LED on a high thermal conductivity nitride substrate with reduced thermal boundary layer of the present invention.

FIG. 6 is a side view of a graded boundary in a LED for reduced thermal boundary layer of the present invention.

FIG. 7 is a side view of a high aspect ratio LED design to increase the thermal extraction area of the present invention.

### DETAILED DESCRIPTION OF DRAWINGS

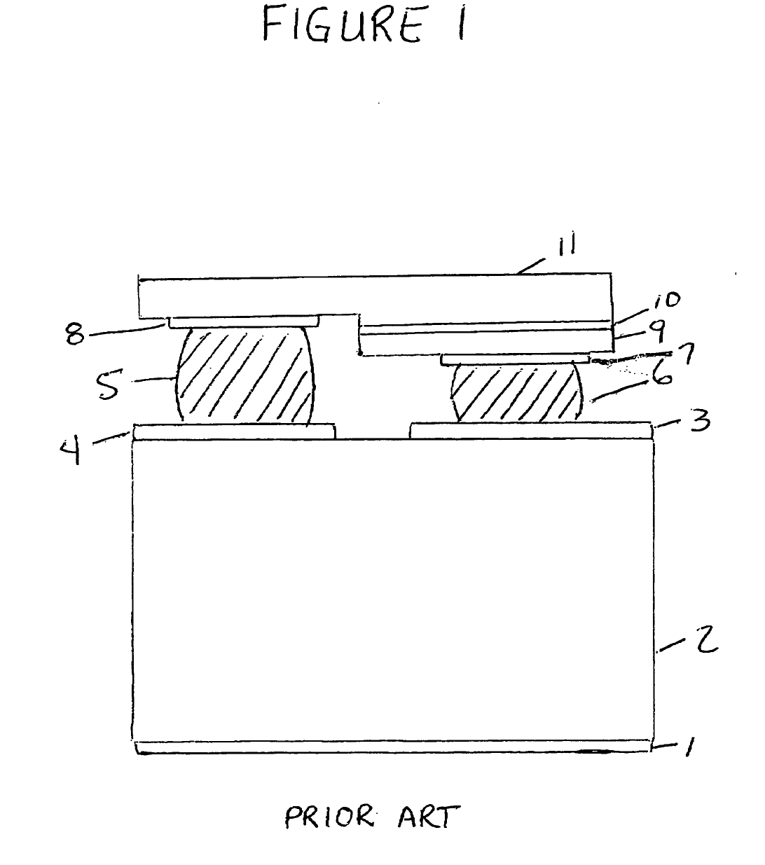

FIG. 1 depicts a typical flip chip mounted LED with a phosphor coating or wavelength conversion chip. The LED semiconductor structure 9 is on the order of 2 to 3 microns of thickness, which requires it to be mounted onto a support substrate 2. The support substrate serves also as the electrical interconnect means for the semiconductor structure. This structure however leads to the introduction of numerous thermal impedance layers. Electrical interconnect means 3 and 4 on the support substrate 2 typically require a minimum of one adhesion layer and one conductive layer. The mounting layer 1 also consists of multiple metallization coatings. Heat generated by the active region 10 within the semiconductor structure 9 principally travels through interconnect means 8 and 7 and then through solder connection 5 and 6 through the interconnect means 3 and 4 to the support substrate 2. Typically semiconductor structure 11 includes the growth substrate such as sapphire or SiC and the n doped region of the LED, however the authors have previously disclosed the use freestanding HVPE with extraction elements for semiconductor structure 11 as well.

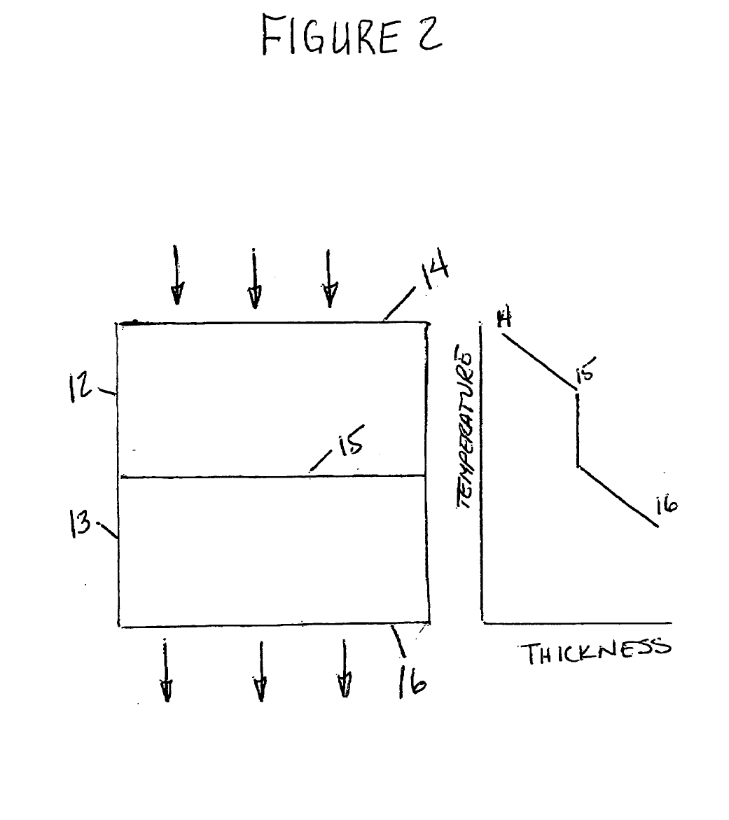

FIG. 2 depicts a typical epitaxial thermal boundary layer between two materials. As an example, GaN 12 grown on SiC 13 will have a well defined epitaxial thermal boundary region 15 for heat entering surface 14 and leaving surface 16. The associated chart shows how a fairly clearly defined discontinuity is present at epitaxial thermal boundary layer 15. Both the GaN 12 and SiC 13 exhibit a fairly uniform temperature gradient through the materials. If the thermal conductivity is sufficiently high and the power density is high, epitaxial thermal boundary region 15 represents the largest thermal impedance in the device between the active region and the cooling means. Multiple thermal boundaries can have a significant impact on overall semiconductor device performance.

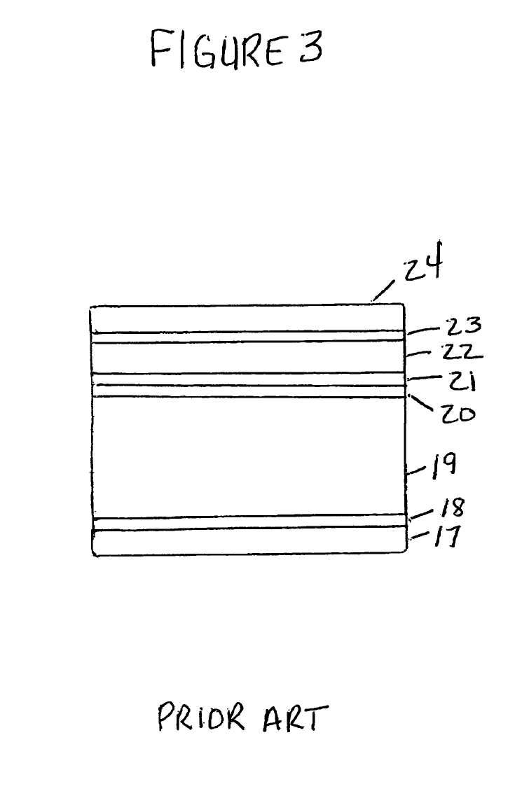

FIG. 3 depicts laser liftoff LED 24 attached via adhesion layer 23, solder layer 22, support metallization layer 21, support adhesion layer 20, support 19, support bottom adhesion layer 18, and bottom support solder 17. Each adhesion layer, solder, and metallization layer constitutes a thermal boundary layer. For low power density applications the main issue is adhesion for these layers since dissimilar materials are being used. As an example, a thin layer of Ti maybe used as support bottom adhesion layer 18 to provide adhesion between the support 19, which is typically sapphire, and the bottom support solder 17. In many cases, multiple depositions are required even within the layers. Thin native nitride semiconductor layers eliminate most of these thermal boundary layers because support metallization layer 21, support adhesion layer 20, support 19, support bottom adhesion layer 18, and bottom support solder 17 are no longer needed because LED 24 has sufficient structural integrity to be die bonded by itself using only adhesion layer 23 and solder layer 22. In this manner several thermal boundary interfaces are eliminated and higher power density devices can be realized.

Light emitting diodes (LEDs) can be fabricated by epitaxially growing multiple layers of semiconductors on a growth substrate. Inorganic light-emitting diodes can be fabricated from GaN-based semiconductor materials containing gallium nitride (GaN), aluminum nitride (AlN), aluminum gallium nitride (AlGaN), indium nitride (InN), indium gallium nitride (InGaN) and aluminum indium gallium nitride (AlInGaN). Other appropriate materials for LEDs include, for example, aluminum gallium indium phosphide (AlGaInP), gallium arsenide (GaAs), indium gallium arsenide (InGaAs), indium gallium arsenide phosphide (InGaAsP), diamond or zinc oxide (ZnO).

The thin nitride semiconductor layers (known as veneers) are preferably between 20 and 150 microns thick with a surface greater than 0.5 cm2. Even more preferably, the nitride veneer is between 30 and 100 microns thick and greater than 1 cm2 in area. The nitride veneer may be doped, undoped, or semi-insulating. Gallium nitride is a preferred embodiment, however all dilute nitrides are also embodiments of this invention. The nitride veneer may be doped with a variety of materials including, but not limited to, Si, Mg, Zn, Ga, Fe, and rare earths. These dopants may be uniformly or non-uniformly doped into the nitride veneer. The dopant levels may be up to and including degenerative levels. The dopants may be used to impart conductivity, semi-insulating and/or luminescent properties to the freestanding nitride veneer. The nitride veneer may consist of any dilute nitride including but not limited to GaN, AlGaN, InGaN, AlInGaN, as well as alloys of As and P. Most preferred are GaN doped with at least one of the following dopants, Si, Zn, Mg, Ga, Al, and rare earths.

The flexible HVPE GaN semiconductor layers of FIG. 3 are 30 microns thick and an area exceeding 1 cm2. These veneers also enable semiconductor structure designs with low overall thermal impedance due to the thin nature of the devices. Semiconductor devices can be created using these native growth semiconductor layer in which the direction of flow for phonons is substantially different than the direction of flow for the electrons within the semiconductor device. If a substantially native semiconductor layer is created via HVPE, thermal boundary resistances can also be reduced during epitaxial device growth due to less stress induced between the various nitride alloy layers.

An alternate method of forming all nitride semiconductor devices is based on the removal of 20 to 150 micron thick HVPE layers from templates by laser liftoff or other separation techniques. These thin all nitride semiconductor layers are flexible in nature, which allows for control/modification of stresses, adherence to non-flat surfaces such as heatpipes, and provides an epitaxial-ready surface without the need for any polishing steps. These thin flexible semiconductor layers are ideal for high powered applications because they do not require additional thinning processes typically required in wafer based approaches. By using these thin, flexible, epi-ready native nitride semiconductor layers, wafer polishing and die thinning steps can be eliminated for the fabrication of high powered devices while allowing access to both sides of the device. This allows device designs in which the direction of phonon flow is not the same as the direction of flow of electrons through the device. Another benefit of the flexible native nitride semiconductor layers approach is that once the nitride layer thickness exceeds 20 microns, dislocation defect density significantly decreases and thermal conductivity increases providing many of the benefits found in thicker growth layers at a fraction of the cost. This coupled with the ability to mediate the stresses within thin flexible layer during device growth and operation can lead to improved device performance.

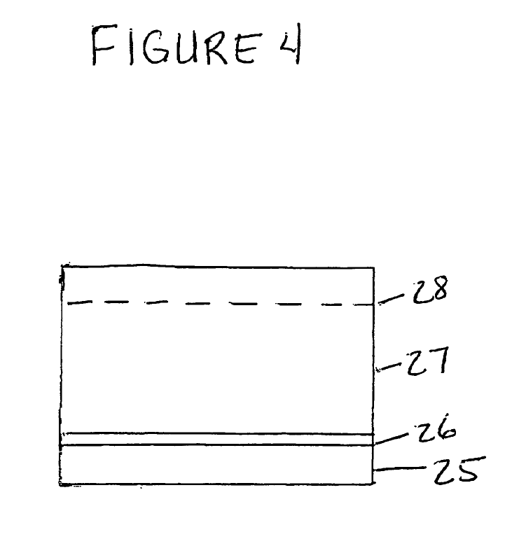

FIG. 4 depicts a thick substantially native HVPE semiconductor structure 27 with a thermal conductivity greater than 120 W/m/K and a die area between 0.01 mm2 and 3000 mm2. In this Figure, a substantially native HVPE semiconductor structure 27 leads to a low thermal impedance boundary 28 for subsequent nitride based devices which may be grown on substantially native HVPE die 27. If the die is to be mounted to a separate heatsinking means, then adhesion layer 26 and die attach layer 25 will still be required. However, the other typical thermal boundary layers associated with non-native substrates have been eliminated.

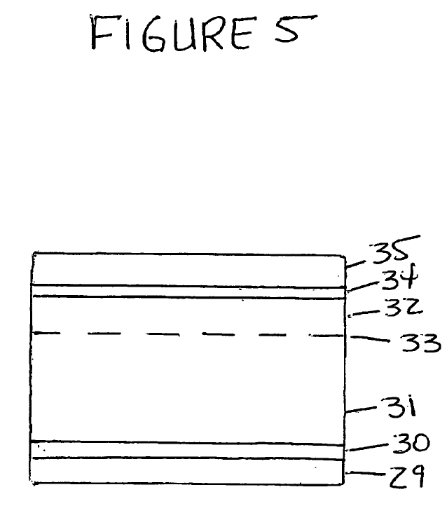

FIG. 5 depicts a low thermal impedance semiconductor structure in which a substantially native HVPE semiconductor structure 31 is used to grow a single heterojunction device. In this case, active region 32 is substantially similar to the substantially native HVPE semiconductor structure 31 such that thermal boundary 33 is minimized. Barrier layer 34 and contact layer 35 are required to form the semiconductor device. Typically barrier layer 34 is compositional different from active region 32 which leads to a significant thermal boundary layer which impedes the flow of phonons in that direction. Barrier layer 34 is however needed to allow operation of the semiconductor structure device at high current levels especially due to leakage of electrons across the active region 32. This is due to the increased mobility of electrons relative to hole mobility within the device. At high current levels, electrons tend to overrun the active region before recombination with a hole can occur. In addition, the contact layer 35 is typically is p type material which is based on Mg doped GaN which is much more difficult to grow with reasonable crystal quality. Thermal conductivity is a function of crystal quality as such high thermal conductivity p type nitride material is more difficult to grow. Therefore the elimination of non-native boundary layers based on using native nitride substrates and the elimination of internal thermal boundaries based creates a device structure such that the direction of phonon flow from the active region 32 to the adherence layer 30 is substantially different from the direction of electron flow through the device is disclosed. Adherence layer 30 and attach means 29 also are depicted and are typically required to allow for the attachment of the semiconductor structure to the desired cooling means. Because substantially no internal thermal boundary layer exists between adherence layer 30 and active region 32, improved thermal performance can be realized. Similar device designs for single quantum wells, multiple quantum wells, 2DEG, as well as other active region structures, are also embodiments. In general, nitride devices in which phonons do not have to cross electron barrier layers to get from the active region 32 of the semiconductor structure device to the cooling means are embodiments of this invention.

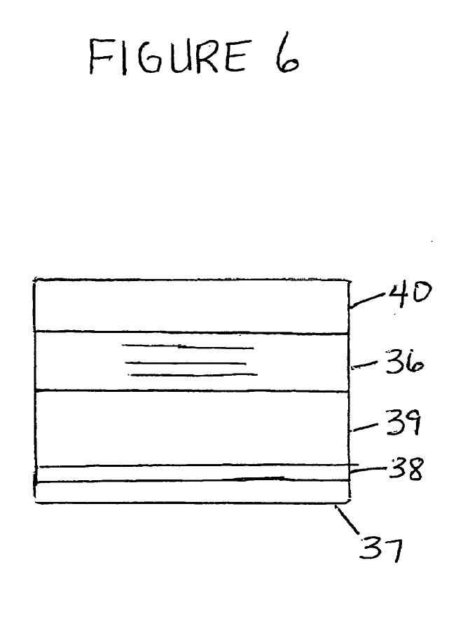

FIG. 6 depicts reduction of the thermal boundary resistance by the introduction of a graded epitaxial growth nitride region 36 between two substantially different epitaxial nitride materials 39 and 40. This approach reduces phonon reflections relative to a clearly defined boundary within or onto a nitride veneer. In a manner similar to an anti-reflection coating on a glass slide reduces reflections at the glass air interface, grading the composition between two different nitride material compositions can be reduce the reflections and scattering of phonons between the two nitride layers. This graded epitaxial growth region 36 maybe grown via HVPE, MOCVD, MBE, ALD, as well as other growth methods for nitride alloys known in the art. The direction phonon flow is substantially different than the direction of electron flow within the device.

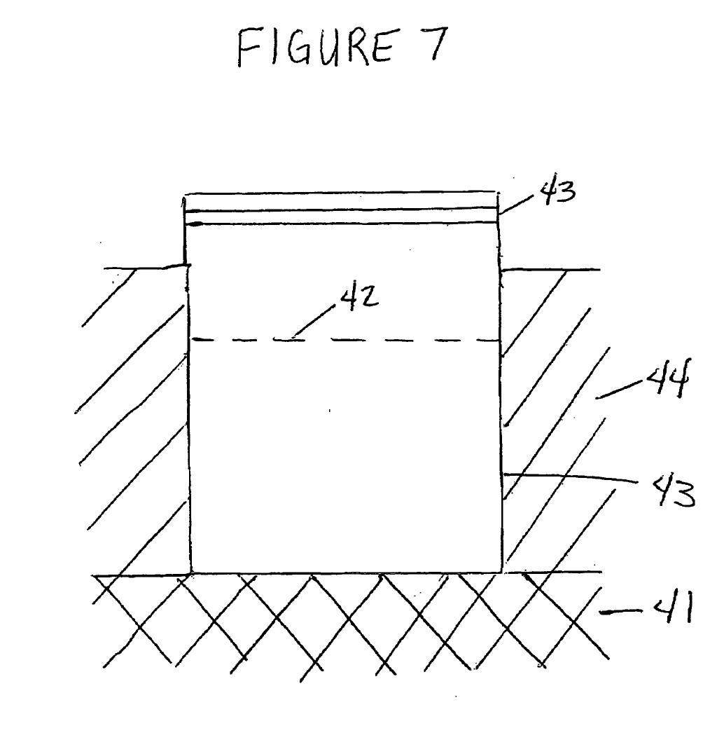

FIG. 7 depicts the use of geometry to reduce thermal boundary resistance. In this case, the nitride semiconductor structure 42 exhibits a semiconductor structure area to semiconductor structure thickness ratio less than 0.1 mm2/micrometer and, more preferably, 0.001 mm2/micrometer. This geometry allows for significant heat flow through the sides of the semiconductor structure as well as the bottom surface. With the use of thick substantially nitride layers formed by HVPE, the amount of surface area available for heatsinking can be higher on the sides of the die than the base of the die. In this manner heat can be extracted 3 dimensionally rather than the more normal 2 dimensional method. Thermal extraction means 44 extracts heat from the sides of the die and, in some cases, can even completely shunt around thermal boundary layer 42. It may also be used in conjunction with bottom heat extraction mean 41. In this manner, more heat can be removed from active region 43 of the semiconductor structure. As stated earlier, the combination of high thermal conductivity of HVPE nitrides and thickness enables the use of this approach. This method can be superior to thin layers because localization of heating near the active region can be reduced for those cases where thermal interface boundaries dominate the thermal impedance of the semiconductor structure device.

While the invention has been described with the inclusion of specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

1. A low thermal impedance semiconductor structure comprising
a plurality of nitride semiconductor layers, each nitride semiconductor layer being between 20 and 150 microns thick with a surface area greater than 0.5 cm2.

2. The low thermal impedance semiconductor structure of claim 1 wherein said each nitride semiconductor layer being between 30 and 100 microns thick with a surface area greater than 1 cm2.

3. The low thermal impedance semiconductor structure of claim 1 wherein said low thermal impedance semiconductor structure is a LED, HEMT or solar cell.

4. A low thermal impedance semiconductor structure comprising
at least one nitride semiconductor layer having an average thermal conductivity greater than 120 W/m/K.

5. The low thermal impedance semiconductor structure of claim 4 wherein the thickness of said at least one nitride semiconductor layer is between 20 micrometers and 150 micrometers.

6. The low thermal impedance semiconductor structure of claim 4 wherein the surface area of said at least one nitride semiconductor layer is between 0.01 mm2 and 3000 mm2.

7. The low thermal impedance semiconductor structure of claim 4 wherein said low thermal impedance semiconductor structure is a LED, HEMT or solar cell.

8. A low thermal impedance semiconductor light emitting diode structure comprising
a plurality of nitride semiconductor layers having an active region for the emission of light, an adherence layer on said active region and a contact layer on said adherence layer.

9. A low thermal impedance semiconductor structure comprising
a plurality of nitride semiconductor layers including a first nitride semiconductor layer of a first nitride semiconductor material, a graded nitride semiconductor region and a second nitride semiconductor layer of a second nitride semiconductor material, said second nitride semiconductor material being different from said first nitride semiconductor material.

10. A low thermal impedance semiconductor structure comprising
a plurality of nitride semiconductor layers, wherein the area of said plurality of nitride semiconductor layers to the thickness of said plurality of nitride semiconductor layers is a ratio of less than 0.1 mm2/micrometer.

11. The low thermal impedance semiconductor structure of claim 10 wherein said ratio is less than 0.001 mm2/micrometer.

12. The low thermal impedance semiconductor structure of claim 10 further comprising
thermal extraction means at least partially surrounding said plurality of nitride semiconductor layers.
